(19) United States
(12) Patent Application Publication
(10) Pub. No.: US 2024/0180016 A1
(43) Pub. Date: May 30, 2024

(54) METHOD OF MANUFACTURING DISPLAY DEVICE

(71) Applicant: Japan Display Inc., Tokyo (JP)

(72) Inventors: Masaru TAKAYAMA, Tokyo (JP); Takanobu TAKENAKA, Tokyo (JP); Hirofumi MIZUKOSHI, Tokyo (JP); Yuki HAMADA, Tokyo (JP)

(73) Assignee: Japan Display Inc., Tokyo (JP)

(21) Appl. No.: 18/498,051

(22) Filed: Oct. 31, 2023

(30) Foreign Application Priority Data
Nov. 25, 2022 (JP) 2022-188205

(51) Int. Cl. H10K 71/60; H10K 71/20

(52) U.S. Cl. CPC H10K 71/60; H10K 71/233; H10K 59/871

(57) ABSTRACT

According to one embodiment, a method of manufacturing a display device, includes forming a lower electrode on a base including a first main surface and a side surface, the lower electrode being on the first main surface of the base, forming a rib including a pixel aperture, forming a partition on the rib, forming a first deposition film which includes a first organic layer which covers the lower electrode via the pixel aperture and a first upper electrode which covers the first organic layer and forming a first sealing layer which covers the first deposition film. The first sealing layer includes a first upper end portion which covers the first deposition film and a first side end portion which covers the side surface.

### CROSS-REFERENCE TO RELATED APPLICATIONS

This application is based upon and claims the benefit of priority from Japanese Patent Application No. 2022-188205, filed Nov. 25, 2022, the entire contents of which are incorporated herein by reference.

### FIELD

Embodiments described herein relate generally to a method of manufacturing a display device.

### BACKGROUND

In recent years, display devices to which an organic light-emitting diode (OLED) is applied as a display element have been put into practical use. Such a display element comprises a lower electrode, an organic layer which covers the lower electrode, and an upper electrode which covers the organic layer.

Incidentally, the display device described above is manufactured by preparing a mother substrate including a plurality of panel portions and using each of the panel portions cut from the mother substrate. In the process of manufacturing such a display device, there is a need for a technology to suppress the degradation of reliability of the display device.

### BRIEF DESCRIPTION OF THE DRAWINGS

FIG. 1 is a diagram showing a configuration example of a display device according to an embodiment.

FIG. 2 is a diagram showing an example of layout of subpixels.

FIG. 3 is a schematic cross-sectional view of the display device taken along line III-III in FIG. 2.

FIG. 4 is a plan view schematically showing a mother substrate for display devices.

FIG. 5 is a flowchart showing an example of a method of manufacturing the display device.

FIG. 6 is a schematic cross-sectional view of a part of the manufacturing process of the display device.

FIG. 7 is a schematic cross-sectional view showing a manufacturing step, which follows that of FIG. 6.

FIG. 8 is a schematic cross-sectional view showing a manufacturing step, which follows that of FIG. 7.

FIG. 9 is a schematic cross-sectional view showing a manufacturing step, which follows that of FIG. 8.

FIG. 10 is a schematic cross-sectional view showing a manufacturing step, which follows that of FIG. 9.

FIG. 11 is a schematic cross-sectional view showing a manufacturing step, which follows that of FIG. 10.

FIG. 12 is a schematic cross-sectional view showing a manufacturing step, which follows that of FIG. 11.

FIG. 13 is a schematic cross-sectional view of a part of the manufacturing process of the display device.

FIG. 14 is a schematic cross-sectional view showing a manufacturing step, which follows that of FIG. 13.

FIG. 15 is a schematic cross-sectional view showing a manufacturing step, which follows that of FIG. 14.

FIG. 16 is a schematic cross-sectional view showing a manufacturing step, which follows that of FIG. 15.

FIG. 17 is a schematic cross-sectional view of another example of the method of manufacturing the display device.

FIG. 18 is a schematic cross-sectional view of a part of a manufacturing process of a display device according to a comparative example.

### DETAILED DESCRIPTION

In general, according to one embodiment, a method of manufacturing a display device, comprises forming a lower electrode on a base including a first main surface on which a plurality of display elements are formed and a side surface connected to the first main surface, the lower electrode being on the first main surface of the base, forming a rib including a pixel aperture which overlaps the lower electrode, forming a partition on the rib, forming a first deposition film which includes a first organic layer which covers the lower electrode via the pixel aperture and a first upper electrode which covers the first organic layer and forming a first sealing layer which covers the first deposition film. The first sealing layer includes a first upper end portion which covers the first deposition film and a first side end portion connected to the first upper end portion, which covers the side surface.

According to such an embodiment, it is possible to provide a method of manufacturing a display device, which can suppress the degradation of the reliability.

Embodiments will be described with reference to the accompanying drawings.

Note that the disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated in the drawings schematically, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X, a direction parallel to the Y-axis is referred to as a second direction Y, and a direction parallel to the Z-axis is referred to as a third direction Z. The third direction Z is normal to a plane containing the first direction X and the second direction Y. Further, viewing structural elements parallel to the third direction Z is referred to as plan view.

The display device of the embodiment is an organic electroluminescent display device comprising an organic light-emitting diode (OLED) as a display element, and could be mounted on televisions, personal computers, in-vehicle devices, tablets, smartphones, mobile phones and the like.

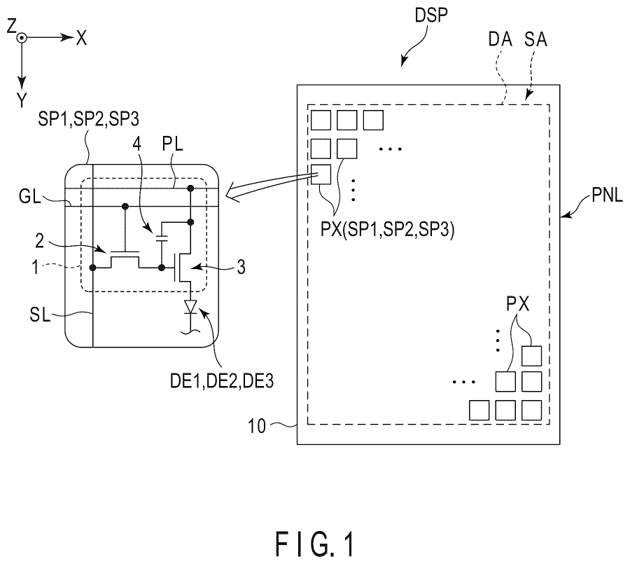

FIG. 1 is a diagram showing a configuration example of a display device DSP according to an embodiment. The display device DSP comprises display panel PNL including a display area DA which displays images and a surrounding area SA around the display area DA, on an insulating base 10. The base 10 may be glass or a flexible resin film.

In this embodiment, the shape of the base 10 in plan view is rectangular. Note here that the shape of the base 10 in plan view is not limited to rectangular, but may as well be some other shape such as a square, circle or oval.

The display area DA comprises a plurality of pixels PX arranged in a matrix along the first direction X and the second direction Y. The pixels PX each include a plurality of subpixels SP1, SP2 and SP3. For example, the subpixels SP1 are blue, the subpixels SP2 are green and the subpixels SP3 are red. Note that the pixels PX may include a subpixel SP of some other color, such as white, together with or in place of any of the subpixels SP1, SP2 and SP3.

The subpixels SP1, SP2 and SP3 comprise a pixel circuit 1 and display elements DE1, DE2 and DE3, respectively, driven by the pixel circuit 1. The pixel circuit 1 comprises a pixel switch 2, a drive transistor 3 and a capacitor 4. The pixel switch 2 and the drive transistor 3 are switching elements constituted by thin-film transistors, for example.

A gate electrode of the pixel switch 2 is connected to a respective scanning line GL. One of source and drain electrodes of the pixel switch 2 is connected to a respective signal line SL, and the other is connected to a gate electrode of the drive transistor 3 and a capacitor 4. In the drive transistor 3, one of source and drain electrodes is connected to a feed line PL and the capacitor 4, and the other is connected to the display element DE1, DE2 or DE3.

The display elements DE1, DE2 and DE3 are each an organic light emitting diode (OLED) as a light emitting element. For example, the subpixels SP1 comprise a display element DE which emits light of a wavelength range of blue color, the subpixels SP2 comprise a display element DE which emits light of a wavelength range of green color, and the subpixels SP3 comprise a display element DE which emits light of a wavelength range of red color.

Note that the configuration of the pixel circuit 1 is not limited to that of the example shown in the figure. For example, the pixel circuit 1 may as well comprise more thin-film transistors and capacitors.

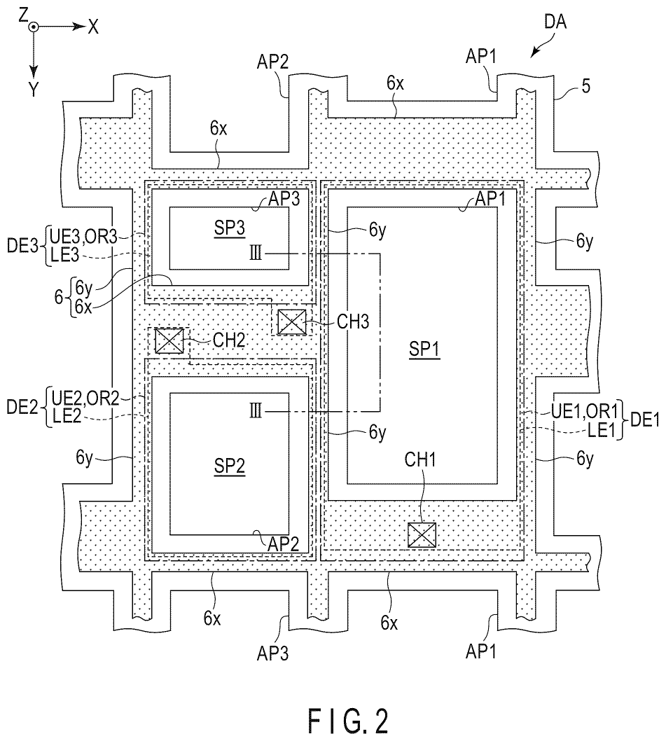

FIG. 2 is a diagram showing an example of layout of the subpixels SP1, SP2 and SP3. In the example shown in FIG. 2, the subpixel SP1 and the subpixel SP2 are aligned along the first direction X. Further, the subpixel SP1 and the subpixel SP3 as well are aligned along the first direction X. Further, the subpixel SP2 and the subpixel SP3 are aligned along the second direction Y.

When the subpixels SP1, SP2 and SP3 have such a layout, rows in each of which subpixels SP2 and SP3 are arranged alternately along the second direction Y in the display area DA. These rows are alternately arranged along the first direction X.

Note that the layout of the subpixels SP1, SP2 and SP3 is not limited to that of the example shown in FIG. 2. As another example, the subpixels SP1, SP2, and SP3 in each pixel PX may as well be aligned in order along the first direction X.

In the display area DA, a rib 5 and a partition 6 are arranged. The rib 5 includes a pixel aperture AP1 in the subpixel SP1, a pixel aperture AP1 in the subpixel SP2 and a pixel aperture AP3 in the subpixel SP3.

In the example shown in FIG. 2, the pixel aperture AP1 is larger in area than the pixel aperture AP2 and the pixel aperture AP1 is larger in area than the pixel aperture AP3. Further, the area of the pixel aperture AP3 is smaller than that of the pixel aperture AP2.

The partition 6 is placed at the boundary of each pair of subpixels SP1, SP2 and SP3 adjacent to each other. The partition 6 overlaps the rib 5 in plan view. The partition 6 includes a plurality of first partitions 6x extending along the first direction X and a plurality of second partitions 6y extending along the second direction Y.

The first partitions 6x are each disposed between each respective pair of pixel apertures AP2 and pixel apertures AP3 adjacent to each other along the second direction Y and between each respective pair of pixel apertures AP1 adjacent to each other along the second direction Y. The second partitions 6y are each disposed between each respective pair of pixel apertures AP1 and pixel apertures AP2 adjacent to each other along the first direction X and between each respective pair of pixel apertures AP1 and pixel apertures AP3 adjacent to each other along the first direction X.

In the example shown in FIG. 2, the first partitions 6x and the second partitions 6y are connected to each other. With this structure, the partition 6, as a whole, has a lattice-like shape which surrounds the pixel apertures AP1, AP2 and AP3 in plan view as a whole. It can as well be said that the partition 6 includes apertures in the subpixels SP1, SP2 and SP3, respectively, as in the case of the rib 5.

The subpixel SP1 comprises a lower electrode LE1, an upper electrode UE1 and an organic layer OR1 each overlapping the pixel aperture AP1. The subpixel SP2 comprises a lower electrode LE2, an upper electrode UE2 and an organic layer OR2 each overlapping the pixel aperture AP2. The subpixel SP3 comprises a lower electrode LE3, an upper electrode UE3 and an organic layer OR3 each overlapping the pixel aperture AP3.

The lower electrode LE1, the upper electrode UE1 and the organic layer OR1 constitute the display element DE1 of the subpixel SP1. The lower electrode LE2, the upper electrode UE2 and the organic layer OR2 constitute the display element DE2 of the subpixel SP2. The lower electrode LE3, the upper electrode UE3 and the organic layer OR3 constitute the display element DE3 of the subpixel SP3. The display elements DE1, DE2 and DE3 may further include a cap layer, which will be described later.

The lower electrode LE1 is connected to the pixel circuit 1 of the subpixel SP1 (see FIG. 1) via a contact hole CH1. The lower electrode LE2 is connected to the pixel circuit 1 of the subpixel SP2 via a contact hole CH2. The lower electrode LE3 is connected to the pixel circuit 1 of the subpixel SP3 via a contact hole CH3.

In the example shown in FIG. 2, the contact holes CH2 and CH3 entirely overlap the first partition 6x located between each respective pair of pixel apertures AP2 and pixel apertures AP3 adjacent to each other along the second direction Y. The contact hole CH1 entirely overlaps the first partition 6x located between each respective pair of pixel apertures AP1 adjacent to each other along the second direction Y. As another example, at least a part of the contact holes CH1, CH2 and CH3 may not overlap the respective first partition 6x.

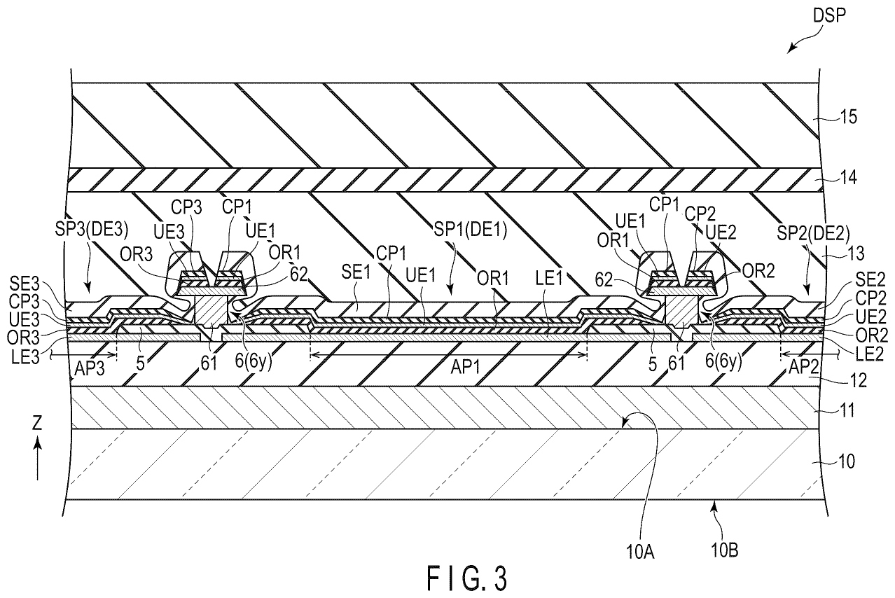

FIG. 3 shows a schematic cross-sectional view of the display device DSP taken along line III-III in FIG. 2. The base 10 includes a main surface 10A and a main surface 10B located on an opposite side to the main surface 10A. The main surface 10A and the main surface 10B are parallel to the X-Y plane defined by the first direction X and the second direction Y. On the main surface 10A of the base 10, a circuit layer 11 is disposed. The circuit layer 11 includes various circuits and wiring lines, such as the pixel circuit 1, scanning lines GL, signal lines SL, and feed lines PL shown in FIG. 1. The circuit layer 11 is covered by an organic insulating layer 12. The organic insulating layer 12 functions as a planarization film that planarizes unevenness created by the circuit layer 11.

The lower electrodes CH1, CH2 and CH3 are all disposed on the organic insulating layer 12, though not illustrated in the cross section shown in FIG. 3.

The lower electrodes LE1, LE2 and LE3 are disposed on the organic insulating layer 12. The rib 5 is disposed on the organic insulating layer 12 and the lower electrodes LE1, LE2 and LE3. End portions of the lower electrodes LE1, LE2 and LE3 are covered by the rib 5. The rib 5 includes the pixel apertures AP1, AP2 and AP3 described above.

The partition 6 includes a lower portion 61 having conductivity and disposed on the rib 5 and an upper portion 62 disposed on the lower portion 61. The upper portion 62 may as well have conductivity as in the case of the lower portion 61. The upper portion 62 has a width greater than that of the lower portion 61. With this configuration, in FIG. 3, both end portions of the upper portion 62 protrude beyond respective side surfaces of the lower portion 61. Such a shape of the partition 6 is referred to as overhanging type.

The organic layer OR1 covers the lower electrode LE1 through the pixel aperture AP1. The upper electrode UE1 covers the organic layer OR1 and opposes the lower electrode LE1. The organic layer OR2 covers the lower electrode LE2 through the pixel aperture AP2. The upper electrode UE2 covers the organic layer OR2 and opposes the lower electrode LE2. The organic layer OR3 covers the lower electrode LE3 through the pixel aperture AP3. The upper electrode UE3 covers the organic layer OR3 and opposes the lower electrode LE3.

In the example shown in FIG. 3, the cap layer CP1 is disposed on the upper electrode UE1, the cap layer CP2 is disposed on the upper electrode UE2, and the cap layer CP3 is disposed on the upper electrode UE3. The cap layers CP1, CP2 and CP3 adjust optical properties of light emitted by the organic layers OR1, OR2 and OR3, respectively.

A portion of each of the organic layer OR1, the upper electrode UE1 and the cap layer CP1 are located on the upper portion 62. This portion is separated from other portions of the organic layer OR1, the upper electrode UE1 and the cap layer CP1.

Similarly, a portion of each of the organic layer OR2, the upper electrode UE2 and the cap layer CP2 is located on the upper portion 62, and this portion is separated from other portions of the organic layer OR2, the upper electrode UE2 and the cap layer CP2.

Further, a portion of each of the organic layer OR3, the upper electrode UE3 and the cap layer CP3 is located on the upper portion 62, and this portion is separated from other portions of the organic layer OR3, the upper electrode UE3 and the cap layer CP3.

A sealing layer SE1 is located in the subpixel SP1, a sealing layer SE2 is located in the subpixel SP2, and a sealing layer SE3 is located in the subpixel SP3.

The sealing layer SE1 continuously covers the portion of the partition 6, which surrounds the subpixel SP1 and is closer to the subpixel SP1, and the cap layer CP1. The sealing layer SE2 continuously covers the portion of the partition 6, which surrounds the subpixel SP2 and is closer to the subpixel SP2, and the cap layer CP2. The sealing layer SE3 continuously covers the portion of the partition 6, which surrounds the subpixel SP3 and is closer to the subpixel SP3, and the cap layer CP3.

Portions (circumferential edge portions) of the sealing layers SE1, SE2 and SE3 are located on the upper portion 62. In the example shown in FIG. 3, the organic layer OR1, the upper electrode UE1, the cap layer CP1 and the sealing layer SE1, which are located on the upper portion 62 of the left portion of the partition 6, are separated from the organic layer OR3, the upper electrode UE3, the cap layer CP3, and the sealing layer SE3, which are located on the upper portion 62.

Further, the organic layer OR1, the upper electrode UE1, the cap layer CP1 and the sealing layer SE1, located on the upper portion 62 of the right portion of the partition 6, are separated from the organic layer OR2, the upper electrode UE2, the cap layer CP2 and the sealing layer SE2, located on the upper portion 62.

The partition 6 is placed at the boundary of each pair of subpixels SP1, SP2 and SP3 adjacent to each other. More specifically, the lower portions 61 of the second partitions 6y (left side of the figure) are located between the organic layer OR1 and the organic layer OR3, between the upper electrode UE1 and the upper electrode UE3 and between the cap layer CP1 and the cap layer CP3, respectively.

Similarly, the lower portions 61 of the second partitions 6y (right side of the figure) are located between the organic layer OR1 and the organic layer OR2, between the upper electrode UE1 and the upper electrode UE2, and between the cap layer CP1 and the cap layer CP2, respectively. The sealing layers SE1, SE2, SE3 individually seal a plurality of display elements DE1, DE2 and DE3.

The sealing layers SE1, SE2 and SE3 are covered by a resin layer 13. The resin layer 13 is covered by a sealing layer 14. Further, the sealing layer 14 is covered by a resin layer 15.

The organic insulating layer 12 and the resin layers 13 and 15 are formed of an organic insulating material. The rib 5, the sealing layers SE1, SE2 and SE3, and the sealing layer 14 are each formed of, for example, an inorganic insulating material such as silicon nitride (SiNx), silicon oxide (SiOx) or silicon oxynitride (SiON).

The lower electrodes LE1, LE2 and LE3 each include an intermediate layer formed of silver (Ag), for example, and a pair of conductive oxide layers which respectively cover an upper surface and lower surface of the intermediate layer. Each conductive oxide layer can be formed, for example, of a transparent conductive oxide such as indium tin oxide (ITO), indium zinc oxide (IZO) or indium gallium zinc oxide (IGZO).

The upper electrodes UE1, UE2 and UE3 are each formed, for example, of a metallic material such as an alloy of magnesium and silver (MgAg). For example, the lower electrodes LE1, LE2 and LE3 correspond to anodes, and the upper electrodes UE1, UE2 and UE3 correspond to cathodes.

The organic layers OR1, OR2 and OR3 have a stacked layer structure of, for example, a hole injection layer, a hole transport layer, an electron blocking layer, a light emitting layer, a hole blocking layer, an electron transport layer and an electron injection layer. The organic layers OR1, OR2 and OR3 may each as well include multiple light emitting layers.

The cap layers CP1, CP2 and CP3 are formed, for example, of a stacked layer body of a plurality of transparent thin films. The stacked layer body may as well include, as the plurality of thin films, a thin film formed of an inorganic material and a thin film formed by an organic material.

Further, these plurality of thin films have refractive indices different from each other. The material of the thin films which constitute the stacked layer body is different from the material of the upper electrodes UE1, UE2 and UE3 and also from the material of the sealing layers SE1, SE2 and SE3. Note here that the cap layers CP1, CP2 and CP3 may be omitted.

To the partition 6, a common voltage is supplied. The common voltage is supplied to each of the upper electrodes UE1, UE2 and UE3, which are in contact with a side surface of the lower portion 61. To the lower electrodes LE1, LE2 and LE3, a pixel voltage is supplied through the respective pixel circuits 1 of the subpixels SP1, SP2 and SP3.

The organic layers OR1, OR2 and OR3 emit light according to the voltage applied thereto. More specifically, when a potential difference is created between the lower electrode LE1 and the upper electrode UE1, the light emitting layer of the organic layer OR1 emits light of a wavelength range of blue color. When a potential difference is created between the lower electrode LE2 and the upper electrode UE2, the light emitting layer of the organic layer OR2 emits light of a wavelength range of green color. When a potential difference is created between the lower electrode LE3 and the upper electrode UE3, the light emitting layer of the organic layer OR3 emits light of a wavelength range of red color.

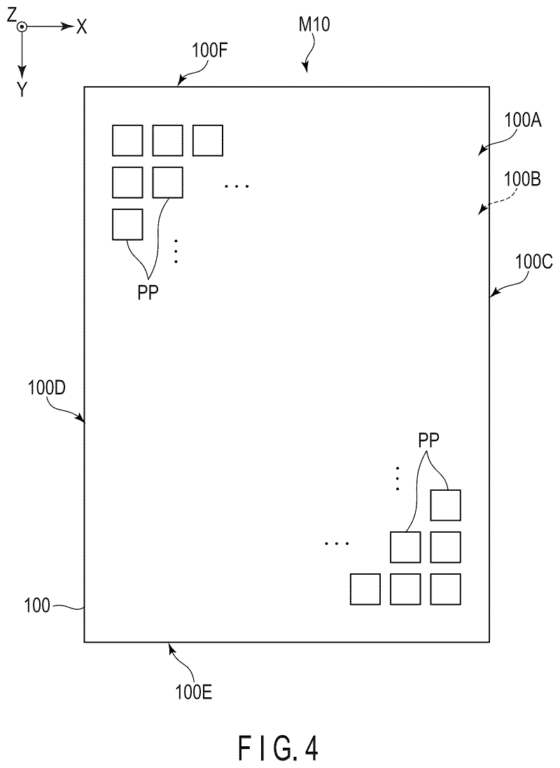

FIG. 4 is a plan view schematically showing a mother substrate M10 for display devices. A plurality of display panels PNL are collectively manufactured in butch using the mother substrate M10 for display devices, (which will be referred to as the mother substrate M10, hereinafter). The mother substrate M10 is rectangular in plan view in this embodiment. But the shape of the mother substrate M10 in plan view is not limited to rectangular.

The mother substrate M10 includes a plurality of panel portions PP. The plurality of panel portions PP are extracted out by cutting the mother substrate M10 along cut lines, which are not shown in the drawing. Each of the cut-out panel portions PP corresponds to the display panel PNL shown in FIG. 1.

The mother substrate M10 includes a base 100. The base 100 includes a first main surface 100A, a second main surface 100B on an opposite side to the first main surface 100A, and side surfaces 100C, 100D, 100E and 100F connected to the first main surface 100A and the second main surface 100B.

The base 10 corresponds to the base 100 obtained after cutting the mother substrate M10. The main surface 10A corresponds to the first main surface 100A after cutting the mother substrate M10, and the main surface 10B corresponds to the second main surface 100B after cutting the mother substrate M10. The first main surface 100A and the second main surface 100B are parallel to the X-Y plane. On the first main surface 100A, a plurality of display elements DE1, DE2 and DE3 are formed.

The side surfaces 100C and 100D extend in the second direction Y and are aligned along the first direction X. The side surfaces 100C and 100D are parallel to the Y-Z plane defined by the second direction Y and the third direction Z, for example. The side surfaces 100E and 100F extend in the first direction X and are aligned along the second direction Y. The side surfaces 100E and 100F are parallel to the X-Z plane defined by the first direction X and the third direction Z.

Now, a method of manufacturing the display device DSP will be described.

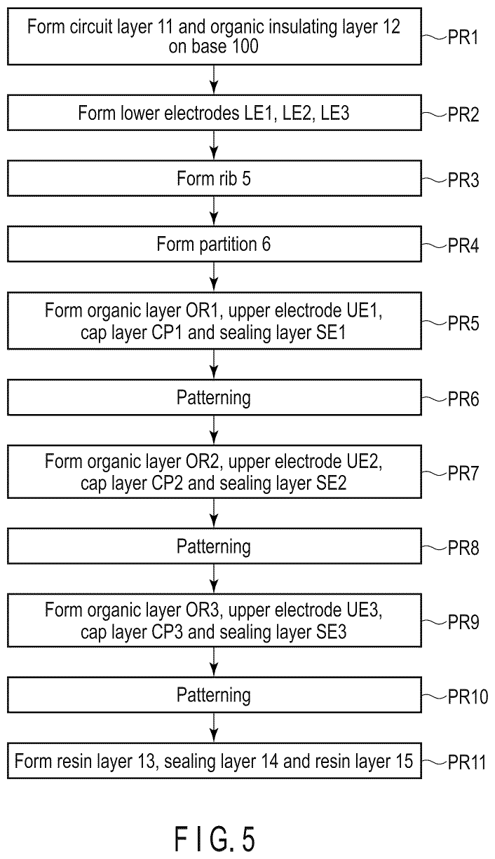

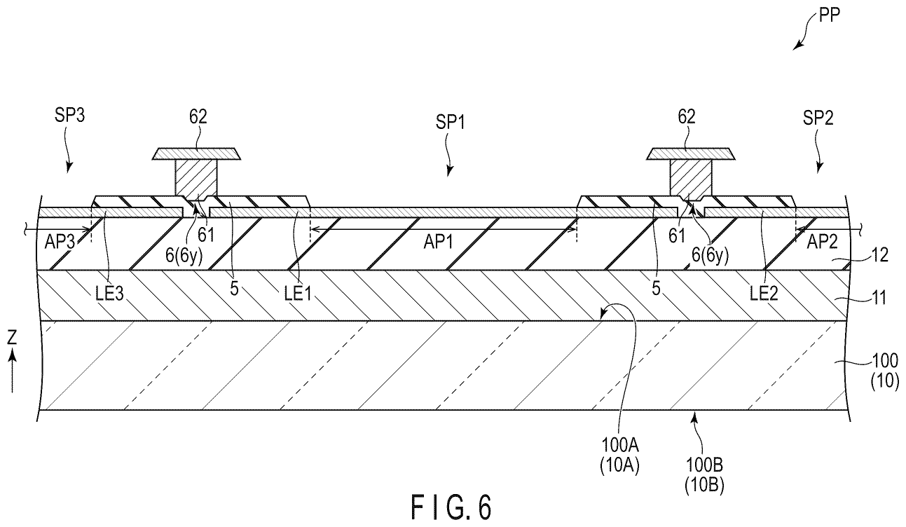

FIG. 5 is a flowchart showing an example of the method of manufacturing the display device DSP. FIGS. 6 to 12 are each a schematic cross-sectional view showing a part of the manufacturing process of the display device DSP. The cross sections shown in FIGS. 6 to 12 each correspond to a cross section of the panel portion PP of the mother substrate M10.

In the manufacturing of the display device DSP, first, the circuit layer 11 and the organic insulating layer 12 are formed on the base 100 (process PR1). The circuit layer 11 is formed at least over the entire display area DA in the panel portion PP. The organic insulating layer 12 is formed to cover the circuit layer 11.

After process PR1, as shown in FIG. 6, the lower electrodes LE1, LE2 and LE3 are formed on the organic insulating layer 12 (process PR2). Then, the rib 5 is formed covering the lower electrodes LE1, LE2 and LE3 (process PR3), and the partition 6 is formed on the rib 5 (process PR4).

The lower electrodes LE1, LE2 and LE3 overlap the first main surface 100A while interposing the circuit layer 11 and the organic insulating layer 12 therebetween. The pixel apertures AP1, AP2 and AP3 may be formed before or after the process PR4.

Subsequently, the processing for forming a plurality of display elements DE1, DE2 and DE3 is carried out. In this embodiment, it is assumed that the display element DE1 is formed first, the display element DE2 is formed next, and the display element DE3 is formed last. But note here that the order of forming the display elements DE1, DE2 and DE3 is not limited to that of this example.

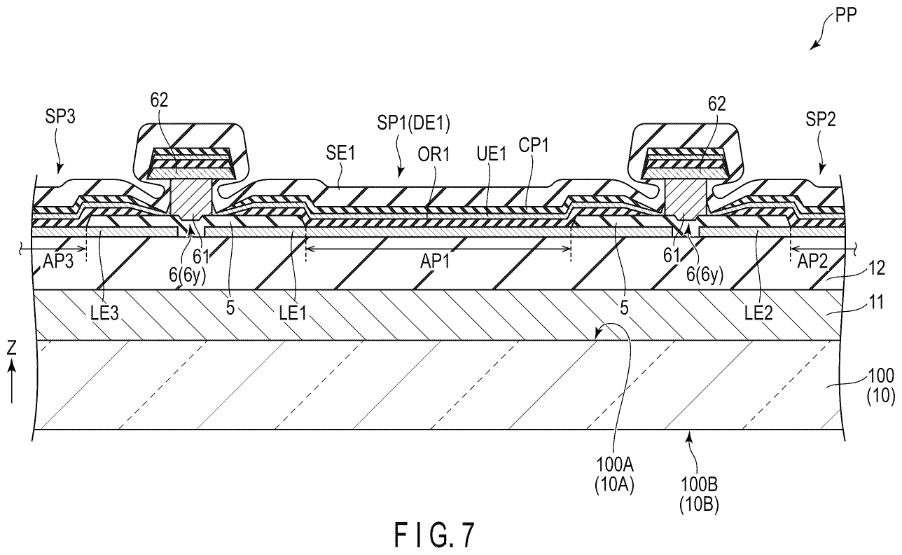

In forming display element DE1, as shown in FIG. 7, the organic layer OR1 which covers the lower electrode LE1 via the pixel aperture AP1, the upper electrode UE1 which covers the organic layer OR1 and the cap layer CP1 which covers the upper electrode UE1 are formed in order by vapor deposition, and the sealing layer SE1 which continuously covers the cap layer CP1 and the partition 6 is formed by chemical vapor deposition (CVD) (process PR5).

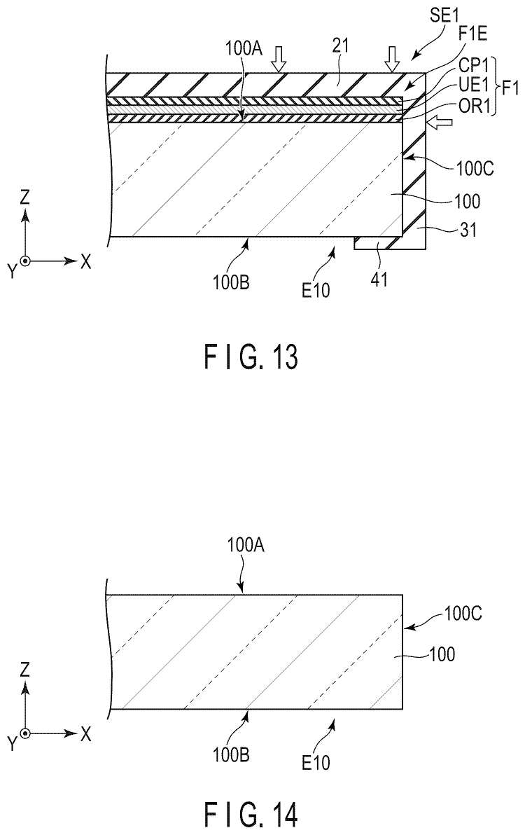

In this embodiment, the organic layer OR1 corresponds to the first organic layer, the upper electrode UE1 corresponds to the first upper electrode, and the sealing layer SE1 corresponds to the first sealing layer. Hereafter, the organic layer OR1, the upper electrode UE1 and the cap layer CP1 may collectively be referred to as a first deposition film F1 (shown in FIG. 13). It can be said that the sealing layer SE1 covers the first deposition film F1.

The organic layer OR1, the upper electrode UE1, the cap layer CP1 and the sealing layer SE1 are formed over at least the entire display area DA in the panel portion PP, and are located not only in the subpixel SP1 but also in the subpixels SP2 and SP3 as well.

The organic layer OR1, the upper electrode UE1, and the cap layer CP1 are divided from each other by the overhanging partition 6. In terms of the mother substrate M10, the organic layer OR1, the upper electrode UE1, the cap layer CP1 and the sealing layer SE1 are formed on the base 100 in its entirety.

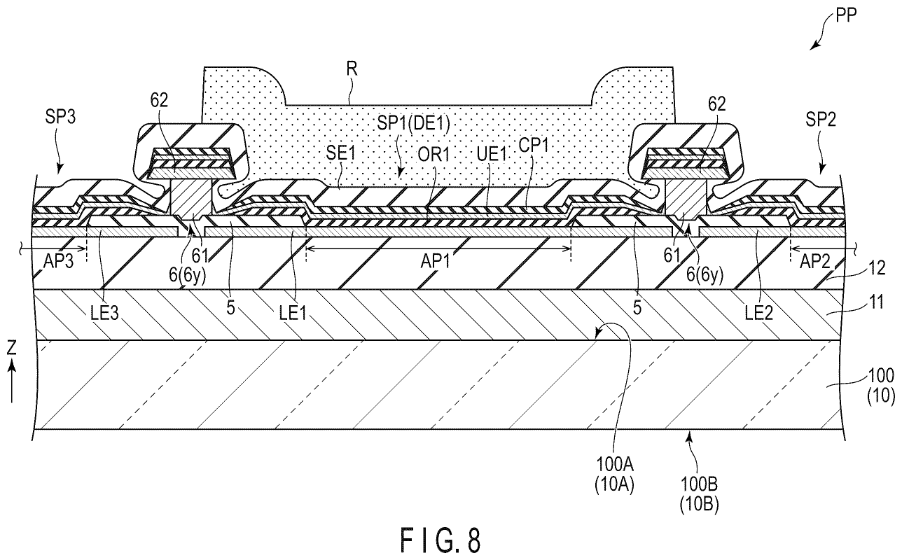

In the flowchart shown in FIG. 5, after the process PR5, the organic layer OR1, the upper electrode UE1, the cap layer CP1 and the sealing layer SE1 are patterned (process PR6). In this patterning, a resist R is formed on the sealing layer SE1 as shown in FIG. 8. In this embodiment, the resist R formed in the process PR6 corresponds to a first resist. The resist R covers the subpixel SP1 and a part of the partition 6 which surrounds it.

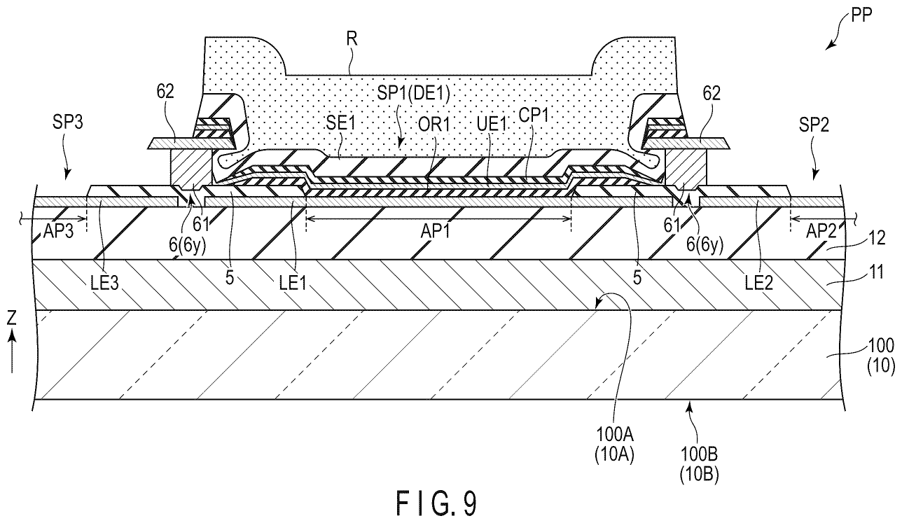

After that, by carrying out etching using the resist R as a mask, the portions of the organic layer OR1, the upper electrode UE1, the cap layer CP1 and the sealing layer SE1, which are exposed from the resist R are removed, as shown in FIG. 9. The etching includes, for example, wet etching and dry etching performed in order on the sealing layer SE1, the cap layer CP1, the upper electrode UE1 and the organic layer OR1.

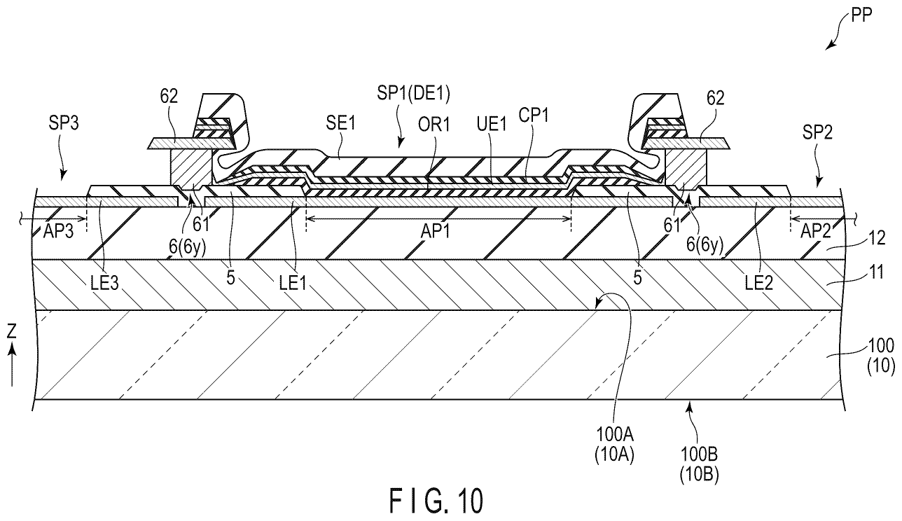

After the process shown in FIG. 9, the resist R is removed. Thus, as shown in FIG. 10, a mother substrate M10 can be obtained on which the display element DE1 and the sealing layer SE1 are formed in the subpixel SP1 and no display element or no sealing layer is formed in the subpixels SP2 and SP3.

The display element DE2 is formed by a procedure similar to that of the display element DE1. That is, after the process PR6, the organic layer OR2 which covers the lower electrode LE2 via the pixel aperture AP2, the upper electrode UE2 which covers the organic layer OR2 and the cap layer CP2 which covers the upper electrode UE2 are formed in order by vapor deposition, and the sealing layer SE2 which continuously covers the cap layer CP2 and the partition 6 is formed by CVD (process PR7).

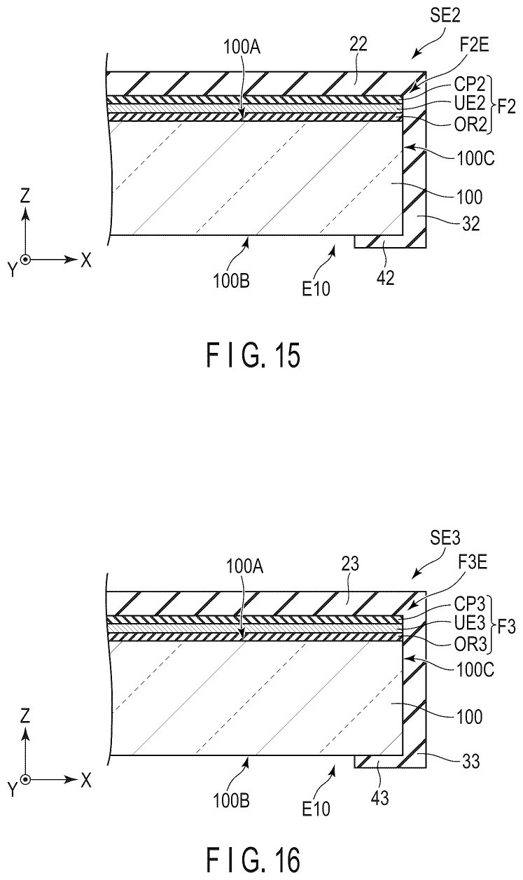

In this embodiment, the organic layer OR2 corresponds to the second organic layer, the upper electrode UE2 corresponds to the second upper electrode, and the sealing layer SE2 corresponds to the second sealing layer. Hereafter, the organic layer OR2, the upper electrode UE2 and the cap layer CP2 may collectively be referred to as a second deposition film F2 (shown in FIG. 15). It can be said that the sealing layer SE2 covers the second deposition film F2.

The organic layer OR2, the upper electrode UE2, the cap layer CP2 and the sealing layer SE2 are formed over at least the entire display area DA in the panel portion PP, and are disposed not only in the subpixel SP2 but also in the subpixels SP1 and SP3. From the viewpoint of the mother substrate M10, the organic layer OR2, the upper electrode UE2, the cap layer CP2 and the sealing layer SE2 are formed on the base 100 in its entirety.

After the process PR7, the organic layer OR2, the upper electrode UE2, the cap layer CP2 and the sealing layer SE2 are patterned by wet etching and dry etching (process PR8). The procedure flow of the patterning is similar to that of the process PR6.

That is, a resist R is formed on the sealing layer SE2. In this embodiment, the resist R formed in the process PR8 corresponds to a second resist. The resist R covers the subpixel SP2 and a part of the partition 6 which surrounds it.

After that, by carrying out etching using the resist R as a mask, the portions of the organic layer OR2, the upper electrode UE2, the cap layer CP2 and the sealing layer SE2, which are exposed from the resist R are removed. Then, the resist R is removed.

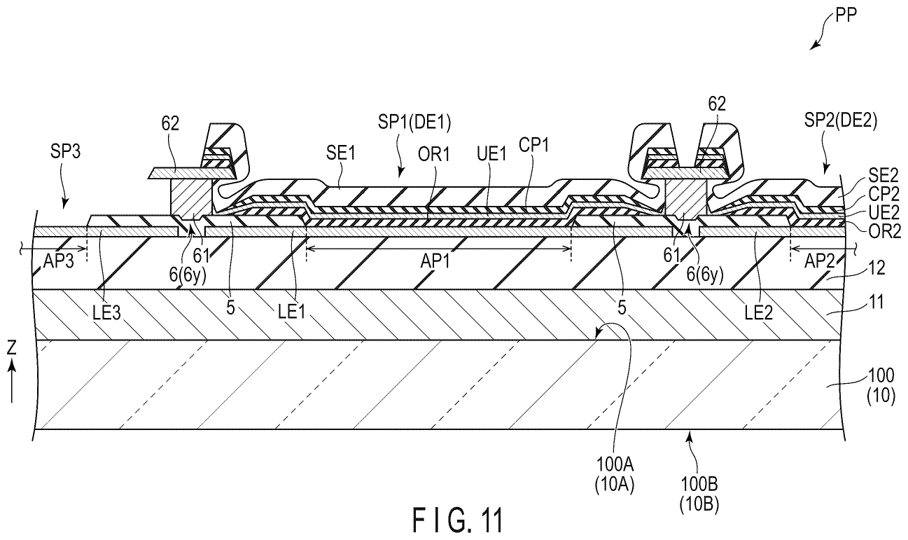

After through the process PR8, as shown in FIG. 11, a mother substrate M10 can be obtained in which a display element DE1 and a sealing layer SE1 are formed in the subpixel SP1, a display element DE2 and a sealing layer SE2 are formed in the subpixel SP2, and no display element or no sealing layer is formed in the subpixel SP3.

The display element DE3 is formed by a procedure similar to that of the display elements DE1 and DE2. That is, after the process PR8, an organic layer OR3 which covers the lower electrode LE3 via the pixel aperture AP3, an upper electrode UE3 which covers the organic layer OR3, and a cap layer CP3 which covers the upper electrode UE3 are formed in order by vapor deposition, and a sealing layer SE3 which continuously covers the cap layer CP3 and the partition 6 is formed by CVD (process PR9).

In this embodiment, the organic layer OR3 corresponds to the third organic layer, the upper electrode UE3 corresponds to the third upper electrode, and the sealing layer SE3 corresponds to the third sealing layer. Hereafter, the organic layer OR3, the upper electrode UE3 and the cap layer CP3 may collectively be referred to as a third deposition film F3 (shown in FIG. 16). It can be said that the sealing layer SE3 covers the third deposition film F3.

The organic layer OR3, the upper electrode UE3, the cap layer CP3 and the sealing layer SE3 are formed over at least the entire display area DA in the panel portion PP, and are disposed not only in the subpixel SP3 but also in the subpixels SP1 and SP2. From the viewpoint of the mother substrate M10, the organic layer OR3, the upper electrode UE3, the cap layer CP3 and the sealing layer SE3 are formed on the base 100 in its entirety.

After the process PR9, the organic layer OR3, the upper electrode UE3, the cap layer CP3 and the sealing layer SE3 are patterned by wet etching and dry etching (process PR10). The flow of the patterning is similar to that of the processes PR6 and PR8.

That is, a resist R is formed on the sealing layer SE3. The resist R covers the subpixel SP3 and a part of the partition 6 which surrounds it. After that, by carrying out etching using the resist R as a mask, the portions of the organic layer OR3, the upper electrode UE3, the cap layer CP3 and the sealing layer SE3, which are exposed from the resist R are removed. Then, the resist R is removed.

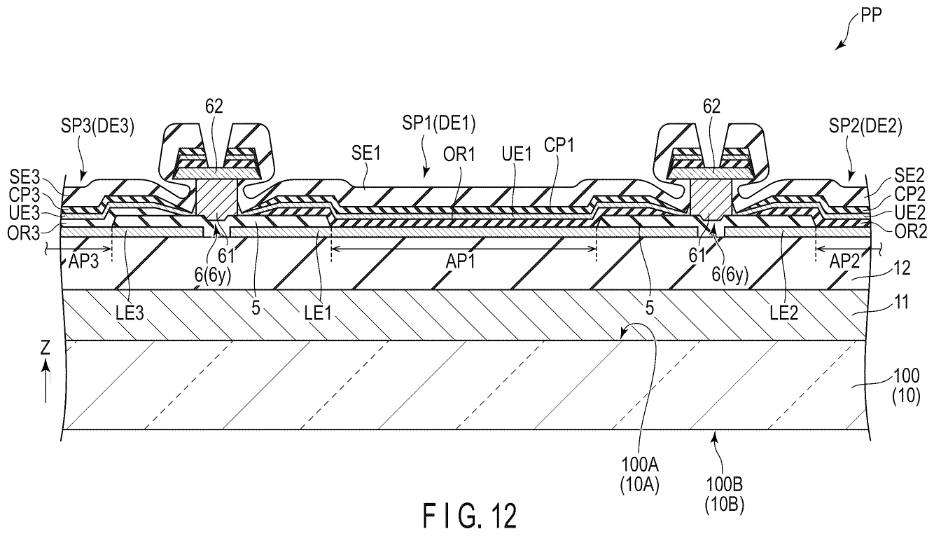

After through the process PR10, as shown in FIG. 12, a mother substrate M10 can be obtained in which a display element DE1 and an sealing layer SE1 are formed in the subpixel SP1, a display element DE2 and an sealing layer SE2 are formed in the subpixel SP2, and a display element DE3 and an sealing layer SE3 are formed in the subpixel SP3.

After forming the display elements DE1, DE2 and DE3 and the sealing layers SE1, SE2 and SE3 are formed, the resin layer 13, the sealing layer 14 and the resin layer 15 shown in FIG. 3 are formed in order (process PR11). After that, through a process in which the panel portion PP is removed from the mother substrate M10, and the like, the display device DSP is completed.

Next, the end portion E10 of the base 100 in the manufacturing process of the display device DSP will be described. FIGS. 13 to 16 are each a schematic cross-sectional view showing a respective part of the manufacturing process of the display device DSP. FIGS. 13 to 16 each show the vicinity of the side surface 100C of the base 100 in the respective processing step in the manufacturing.

In FIGS. 13 to 16, the mother substrate M10 is viewed in the direction opposite to the second direction Y. The base 10 includes an end portion E10. The end portion E10 is located on an outer circumference of the base 100. The end portion E10 includes a side surfaces 100C, 100D, 100E and 100F.

In the process PR5 described above, the first deposition film F1 (the organic layer OR1, the upper electrode UE1 and the cap layer CP1) is formed on the first main surface 100A which is located in the end portion E10 as well. Since the end portion E10 of the base 100 does not include the panel portion PP, the circuit layer 11 and the organic insulating layer 12 are not formed on the end portion E10 of the base 100. As shown in FIG. 13, the organic layer OR1 is in contact with the first main surface 100A in the end portion E10.

In the example shown in FIG. 13, the organic layer OR1 is formed up to the edge of the first main surface 100A. The upper electrode UE1 is disposed on the organic layer OR1, and the cap layer CP1 is disposed on the upper electrode UE1.

The sealing layer SE1 is formed to cover the first deposition film F1 and the end portion E10 of the base 100. The sealing layer SE1 includes a first upper end portion 21, a first side end portion 31 and a first lower end portion 41.

The first upper end portion 21, the first side end portion 31 and the first lower end portion 41 are formed to be integrated by CVD. The thicknesses of the first upper end portion 21, the first side end portion 31 and the first lower end portion 41 may be equal to or different from each other.

The first upper end portion 21 is, for example, located above the first main surface 100A and overlaps the first main surface 100A along the third direction Z. The first upper end portion 21 covers the first deposition film F1. In other words, the first upper end portion 21 is in contact with the first deposition film F1 (the cap layer CP1). The first side end portion 31 is connected to the first upper end portion 21.

The first side end portion 31 covers the side surface 100C. In other words, the first side end portion 31 is in contact with the side surface 100C. The first side end portion 31 covers an end portion F1E of the first deposition film F1.

The first lower end portion 41 is, for example, located below the second main surface 100B and overlaps the second main surface 100B along the third direction Z. The first lower end portion 41 is connected to the first side end portion 31. The first lower end portion 41 extends from the first side end portion 31 in a direction opposite to the first direction X. The first lower end portion 41 covers at least a part of the second main surface 100B. In other words, the first lower end portion 41 is in contact with at least a part of the second main surface 100B.

Thus, the sealing layer SE1 covers the first deposition film F1 and the end portion E10 of the base 100 by the first upper end portion 21, the first side end portion 31 and the first lower end portion 41. As a result, the end portion F1E of the first deposition film F1 is not exposed.

In the process PR6 described above, the vicinity of the end portion E10 is exposed from the resist R. More specifically, the first deposition film F1, the first upper end portion 21, the first side end portion 31 and the first lower end portion 41 located in the end portion E10 correspond to the portions exposed from the resist R.

By etching using the resist R as a mask, carried out in the process PR6, the first upper end portion 21, the first side end portion 31, the first lower end portion 41 and the first deposition film F1 are removed from the end portion E10 of the base 100, as shown in FIG. 14. After through the process PR6, the first main surface 100A, the side surface 100C and the second main surface 100B are exposed in the end portion E10 of the base 100.

In the process PR7 as well, the second deposition film F2 and the sealing layer SE2 are formed on the end portion E10 of the base 100 in a manner similar to that of the process PR5.

That is, the second deposition film F2 (the organic layer OR2, the upper electrode UE2 and the cap layer CP2) is formed on the first main surface 100A which is located in the end portion E10 as well. As shown in FIG. 15, the organic layer OR2 is in contact with the first main surface 100A in the end portion E10.

In the example shown in FIG. 15, the organic layer OR2 is formed up to the edge of the first main surface 100A. The upper electrode UE2 is disposed on the organic layer OR2, and the cap layer CP2 is disposed on the upper electrode UE2.

The sealing layer SE2 is formed to cover the second deposition film F2 and the end portion E10 of the base 100. The sealing layer SE2 includes a second upper end portion 22, a second side end portion 32 and a second lower end portion 42.

The second upper end portion 22, the second side end portion 32 and the second lower end portion 42 are formed to be integrated with each other by CVD. The thicknesses of the second upper end portion 22, the second side end portion 32 and the second lower end portion 42 may be equal to or different from each other.

The second upper end portion 22 covers the second deposition film F2. The second side end portion 32 is connected to the second upper end portion 22. The second side end portion 32 covers the side surface 100C. The second side end portion 32 covers the end portion F2E of the second deposition film F2, as well. The second lower end portion 42 is connected to the second side end portion 32. The second lower end portion 42 covers at least a part of the second main surface 100B.

Thus, the sealing layer SE2 covers the second deposition film F2 and the end portion E10 of the base 100 by the second upper end portion 22, the second side end portion 32 and the second lower end portion 42. As a result, the end portion F2E of the second deposition film F2 is not exposed.

In the process PR8 described above, the second deposition film F2, the second upper end portion 22, the second side end portion 32 and the second lower end portion 42 located in the end portion E10 correspond to the portions exposed from the resist R. By the etching using the resist R as a mask, carried out in the process PR8, the second upper end portion 22, the second side end portion 32, the second lower end portion 42 and the second deposition film F2 are removed from the end portion E10 of the base 100. After through the process PR8, the first main surface 100A, the side surface 100C and the second main surface 100B are exposed in the end portion E10 of the base 100, as in the case of the process PR6.

In the process PR9, the third deposition film F3 and the sealing layer SE3 are formed in the end portion E10 of the base 100 in a manner similar to that of the processes PR5 and PR7.

That is, the third deposition film F3 (the organic layer OR3, the upper electrode UE3 and the cap layer CP3) is formed on the first main surface 100A which is located in the end portion E10 as well. As shown in FIG. 16, the organic layer OR3 is in contact with the first main surface 100A in the end portion E10.

In the example shown in FIG. 16, the organic layer OR3 is formed up to the edge of the first main surface 100A. The upper electrode UE3 is disposed on the organic layer OR3, and the cap layer CP3 is disposed on the upper electrode UE3.

The sealing layer SE3 is formed to cover the third deposition film F3 and the end portion E10 of the base 100. The sealing layer SE3 includes a third upper end portion 23, a third side end portion 33 and a third lower end portion 43.

The third upper end portion 23, the third side end portion 33, and the third lower end portion 43 are formed to be integrated with each other by CVD. The thicknesses of the third upper end portion 23, the third side end portion 33 and the third lower end portion 43 may be equal to or different from each other.

The third upper end portion 23 covers the third deposition film F3. The third side end portion 33 is connected to the third upper end portion 23. The third side end portion 33 covers the side surface 100C. The third side end portion 33 covers the end portion F3E of the third deposition film F3 as well. The third lower end portion 43 is connected to the third side end portion 33. The third lower end portion 43 covers at least a part of the second main surface 100B.

Thus, the sealing layer SE3 covers the third deposition film F3 and the end portion E10 of the base 100 by the third upper end portion 23, the third side end portion 33 and the third lower end portion 43. As a result, the end portion F3E of the third deposition film F3 is not exposed.

In the process PR10 described above, the third deposition film F3, the third upper end portion 23, the third side end portion 33 and the third lower end portion 43 located in the end portion E10 correspond to the portions exposed from the resist R. By the etching using the resist R as a mask, carried out in the process PR10, the third upper end portion 23, the third side end portion 33, the third lower end portion 43 and the third deposition film F3 are removed from the end portion E10 of the base 100. After through the process PR10, the first main surface 100A, the side surface 100C and the second main surface 100B are exposed in the end portion E10 of the base 100, as in the case of the process PR6.

In FIGS. 13 to 16, the end portion E10 in the vicinity of the side surface 100C of the base 100 is described. In the vicinity of each of the side surfaces 100D, 100E and 100F of the base 100 as well, the sealing layers SE1, SE2 and SE3 have configurations similar to each other according to the manufacturing process described above.

That is, in the process PR5, the sealing layer SE1 is formed to cover the first deposition film F1 and the end portion E10 of the base 100 in the vicinities of the side surfaces 100D, 100E and 100F of the base 100.

In the process PR7, the sealing layer SE2 is formed to cover the second deposition film F2 and the end portion E10 of the base 100 in the vicinities of the side surfaces 100D, 100E and 100F of the base 100. In the process PR9, the sealing layer SE3 is formed to cover the third deposition film F3 and the end portion E10 of the base 100 in the vicinities of the side surfaces 100D, 100E and 100F of the base 100.

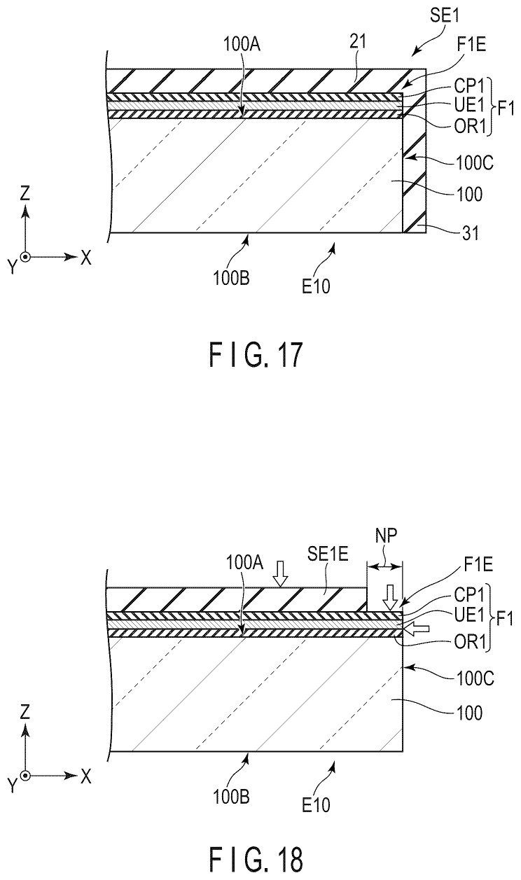

FIG. 17 is a schematic cross-sectional view of another example of the manufacturing process of the display device DSP. The example shown in FIG. 17 is different from that of FIG. 13 in that the sealing layer SE1 does not comprise the first lower end portion 41.

The sealing layer SE1 is formed to cover the first deposition film F1 and the end portion E10 of the base 100. The sealing layer SE1 includes a first upper end portion 21 and a first side end portion 31. The first upper end portion 21 and the first side end portion 31 are formed to be integrated with each other.

In the example shown in FIG. 17, the first side end portion 31 extends downward further from the first main surface 100A. Here, it is preferable that the first side end portion 31 be formed to cover the side surface 100C in its entirety.

Even with the shape described with reference to FIG. 17, the sealing layer SE1 covers the first deposition film F1 by the first upper end portion 21 and the first side end portion 31, and therefore the end portion F1E of the first deposition film F1 is not exposed.

Here, the illustration of FIG. 17 is directed to the sealing layer SE1, but the configuration of the sealing layer SE1 shown in FIG. 17 can as well be applied to the sealing layer SE2 in the process PR7 and the sealing layer SE3 in the process PR9.

FIG. 18 is a schematic cross-sectional view showing a part of the manufacturing process of the display device DSP according to a comparative example. In the example shown in FIG. 18, the sealing layer SE1E does not cover parts of the first deposition film F1 and the end portion E10 of the base 100.

The first deposition film F1 includes, for example, a portion NP which is not covered by the sealing layer SE1E. In other words, a part of the first deposition film F1 is exposed. The width of the uncovered portion NP is, for example, about 10 mm. Furthermore, the side surface 100C of the base 100 is exposed as well.

In such a case, as indicated by the arrow in FIG. 18, moisture can penetrate from above the uncovered portion NP and from the side of the end portion F1E of the first deposition film F1 to between the first main surface 100A and the first deposition film F1, between each adjacent pair of layers which constitute the first deposition film F1 and between the first deposition film F1 and the sealing layer SE1.

Moisture can enter, for example, when the base 100 is exposed to the atmosphere during the manufacturing process, when it is washed during etching or the like. Such moisture penetration may cause the organic layer OR1, for example, which constitutes the first deposition film F1, to peel off. The uncovered portion NP can be a starting point for the layer to peel off. Further, when the organic layer OR1 peels off and the peeled portion becomes a foreign material, it may cause defects such as lowering of the coverage property of the layer to be deposited subsequently, degradation of the display quality and the like. Thus, the peeling-off of the organic layer OR1 can be a cause of the lowering of the reliability of the display device.

According to the method of manufacturing the display device DSP, the sealing layer SE1 which covers the first deposition film F1 includes a first upper end portion 21 and a first side end portion 31. With this configuration, the sealing layer SE1 covers the first deposition film F1 and the end portion E10 of the base 100. In other words, the end portion F1E of the first deposition film F1 is not exposed.

As a result, in each of the locations indicated by the arrows shown in FIG. 13, moisture penetration with respect to the first deposition film F1 can be suppressed between the first main surface 100A and the first deposition film F1, between each adjacent pair of layers which constitute the first deposition film F1, and between the first deposition film F1 and the sealing layer SE1.

Therefore, the risk of peeling off of any layer which constitutes the first deposition film F1 due to moisture penetration can be reduced. As a result, it is possible to suppress the degradation of the reliability of the display device DSP.

In this embodiment, the sealing layer SE1 further includes the first lower end portion 41. With this configuration, it becomes more difficult for moisture to penetrate between the side surface 100C and the first side end portion 31 of the sealing layer SE1. Therefore, the degradation in reliability of the display device DSP can be further suppressed.

According to this embodiment, in each manufacturing process of forming the display elements DE2 and DE3, the sealing layers SE2 and SE2 cover the second deposition film F2, the third deposition film F3, and the end portion E10 of the base 100, as in the case of the sealing layer SE1. Therefore, the penetration of moisture can be prevented in each process of forming the display elements DE1, DE2 and DE3.

As described above, according to the configuration of this embodiment, it is possible to provide a method of manufacturing a display device DSP that can suppress degradation in reliability of the display device DSP. Apart from this, various types of other advantageous effects can be obtained from this embodiment.

Note that in the process PR6, the first side end portion 31 and the first lower end portion 41 are removed by etching, but at least some parts of the first side end portion 31 and the first lower end portion 41 may not necessarily be removed by etching. In this case, a sealing layer SE2 may be formed to cover the remaining sealing layer SE1. Further, a sealing layer SE3 may be formed to cover the remaining sealing layer SE2.

In this embodiment, the first deposition film F1 includes the cap layer CP1, but the first deposition film F1 may not include the cap layer CP1. Similarly, the second deposition film F2 may not include the cap layer CP2, or the third deposition film F3 may not include the cap layer CP3.

All of the manufacturing methods for the display devices that can be implemented by a person of ordinary skill in the art through arbitrary design changes based on the manufacturing methods for the display devices described above as the embodiments and the modified examples of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each of the above embodiments and modified examples and are self-explanatory from the descriptions of the specification or can be arbitrarily conceived by a person of ordinary skill in the art are considered to be naturally brought about by the present invention as a matter of course.

What is claimed is:

1. A method of manufacturing a display device, comprising:
forming a lower electrode on a base including a first main surface on which a plurality of display elements are formed and a side surface connected to the first main surface, the lower electrode being on the first main surface of the base;
forming a rib including a pixel aperture which overlaps the lower electrode;
forming a partition on the rib;
forming a first deposition film which includes a first organic layer which covers the lower electrode via the pixel aperture and a first upper electrode which covers the first organic layer; and
forming a first sealing layer which covers the first deposition film,
the first sealing layer including a first upper end portion which covers the first deposition film and a first side end portion connected to the first upper end portion, which covers the side surface.

2. The method of claim 1, wherein
the base further includes a second main surface on an opposite side to the first main surface, and
the first sealing layer further includes a lower end portion connected to the first side end portion, which covers at least a part of the second main surface.

3. The method of claim 1, further comprising:
forming a first resist on the first sealing layer after forming the first sealing layer;
removing parts of the first sealing layer and the first deposition film, which are exposed from the first resist by etching; and
removing the first resist.

4. The method of claim 3, wherein
the removing the parts of the first sealing layer and the first deposition film, which are exposed from the first resist includes removing the first upper end portion and the first side end portion.

5. The method of claim 1, wherein
the first deposition film further includes a cap layer which covers the first upper electrode.

6. The method of claim 1, wherein
the first sealing layer is formed of an inorganic insulating material.

7. The method of claim 3, further comprising:
forming a second deposition film which includes a second organic layer which covers the lower electrode via the pixel aperture and a second upper electrode which covers the second organic layer, after removing the first resist; and
forming a second sealing layer which covers the second deposition film,
wherein
the second sealing layer includes a second upper end portion which covers the second deposition film and a second side end portion which is connected to the second upper end portion and covers the side surface.

8. The method of claim 7, further comprising:
forming a second resist on the second sealing layer, after forming the second sealing layer;
removing parts of the second sealing layer and the second deposition film, which are exposed from the second resist by etching; and
removing the second resist.

9. The method of claim 8, further comprising:
forming a third deposition film which includes a third organic layer which covers the lower electrode via the pixel aperture and a third upper electrode which covers the third organic layer, after removing the second resist; and
forming a third sealing layer which covers the third deposition film,
wherein
the third sealing layer includes a third upper end portion which covers the third deposition film and a third side end portion which is connected to the third upper end portion and covers the side surface.

10. The method of claim 1, wherein
the partition includes a lower portion disposed on the rib and an upper portion disposed on the lower portion and having a width greater than that of the lower portion.

11. The method of claim 1, wherein
the partition surrounds the pixel aperture in plan view.

12. The method of claim 1, wherein
the first upper end portion and the first side end portion are formed to be integrated with each other.

13. The method of claim 2, wherein
the first upper end portion, the first side end portion and the lower end portion are formed to be integrated with each other.

14. The method of claim 2, further comprising:
forming a first resist on the first sealing layer after forming the first sealing layer;
removing parts of the first sealing layer and the first deposition film, which are exposed from the first resist by etching; and
removing the first resist.

15. The method of claim 14, wherein
the removing the parts of the first sealing layer and the first deposition film, which are exposed from the first resist includes removing the first upper end portion, the first side end portion and the lower end portion.

16. The method of claim 1, wherein
the first side end portion extends downward further from the first main surface.

17. The method of claim 16, wherein
the first side end portion is formed to cover the side surface in its entirety.

18. The method of claim 1, wherein
the first side end portion covers an end portion of the first deposition film.

19. The method of claim 5, wherein
the first upper end portion is in contact with the cap layer.

20. The method of claim 5, further comprising:
forming a third resist on the third sealing layer, after forming the third sealing layer;
removing parts of the third sealing layer and the third deposition film, which are exposed from the third resist by etching; and
removing the third resist.
